(19) United States
(12) Patent Application Publication
(10) Pub. No.: US 2007/0076791 A1
(43) Pub. Date: Apr. 5, 2007

(54) APPROXIMATE CHOLESKY DECOMPOSITION-BASED BLOCK LINEAR EQUALIZER

(75) Inventors: Robert A. DiFazio, Greenlawn, NY (US); Jung-Lin Pan, Selden, NY (US); Bin Li, Ronkonkoma, NY (US); Mihaela C. Beluri, Glen Cove, NY (US)

Correspondence Address: VOLPE AND KOENIG, P.C.;DEPT. ICC, UNITED PLAZA, SUITE 1600, 30 SOUTH 17TH STREET, PHILADELPHIA, PA, 19103, US

(73) Assignee: INTERDIGITAL TECHNOLOGY CORPORATION, Wilmington, DE (US)

(21) Appl. No.: 11/427,217

(22) Filed: Jun. 28, 2006

Related U.S. Application Data
(60) Provisional application No. 60/702,648, filed on Jul. 26, 2005.

(51) Int. Cl. H03H 7/30; H04B 1/00

(52) U.S. Cl. 375/229; 375/147

(57) ABSTRACT

A block linear equalizer (BLE) using an approximate Cholesky decomposition is disclosed. The BLE includes channel estimators, a channel monitor unit, a noise power estimator, a parameter selection unit and an approximate Cholesky processor. The channel estimator generates a channel estimate vector from received samples. The channel monitor unit generates a first channel monitor signal for a truncated channel estimate vector and a second channel monitor signal. The noise power estimator estimates a noise power of the received samples. The parameter selection unit selects parameters for approximate Cholesky decomposition based on the first and second channel monitor signals. The approximate Cholesky processor performs block linear equalization on the received samples based on approximate Cholesky decomposition.

### CROSS REFERENCE TO RELATED APPLICATION

This application claims the benefit of U.S. provisional application No. 60/702,648 filed Jul. 26, 2005, which is incorporated by reference as if fully set forth.

### FIELD OF INVENTION

The present invention is related to a receiver in a wireless communication system. More particularly, the present invention is related to a block linear equalizer (BLE) using an approximate Cholesky decomposition.

### BACKGROUND

A communication channel can be characterized by a signal-to-noise ratio (SNR), multipath fading, multiple access interference (MAI) and other impairments that may be external or internal to a transmitter or a receiver. A variety of receiver architectures have been developed to provide improvements over a Rake-based receiver. However, these receivers generally require significant computational complexity, which requires more components, more software cycles, more processing power and ultimately higher cost terminals having shorter battery life. Therefore, a receiver having reduced computational complexity while providing improved performance is desirable.

### SUMMARY

The present invention is related to a BLE using an approximate Cholesky decomposition. The BLE includes channel estimators, a channel monitor unit, a noise power estimator, a parameter selection unit and an approximate Cholesky processor. The channel estimator generates a channel estimate vector from received samples. The channel monitor unit generates a first channel monitor signal for a truncated channel estimate vector and a second channel monitor signal. The noise power estimator estimates a noise power of the received samples. The parameter selection unit selects parameters for the approximate Cholesky decomposition based on the first and second channel monitor signals. The approximate Cholesky processor performs block linear equalization on the received samples based on the approximate Cholesky decomposition. The block linear equalization may be performed based on a zero forcing (ZF) or minimum mean square error (MMSE) solution. The approximation is implemented by calculating only a portion of matrix elements and repeating certain elements to fill the remaining elements. The parameter selection unit selects parameters such as an update rate, the number of rows or columns to compute before repeating data in the approximate Cholesky decomposition, a block size and edge size based on channel conditions such as coherence time, Doppler spread and power saving parameters.

### BRIEF DESCRIPTION OF THE DRAWINGS

A more detailed understanding of the invention may be had from the following description of a preferred embodiment, given by way of example and to be understood in conjunction with the accompanying drawings wherein:

FIG. 1 is a block diagram of a receiver including an approximate Cholesky-based BLE and descramblers and despreaders configured in accordance with the present invention;

FIG. 2 shows a sliding window operation used in the BLE of FIG. 1;

FIG. 3 shows approximate Cholesky decomposition using repeated rows in accordance with the present invention;

FIG. 4 shows approximate Cholesky decomposition using repeated columns in accordance with the present invention;

FIGS. 5 and 6 are exemplary block diagrams of an approximate Cholesky processor used in the BLE of FIG. 1;

FIGS. 7 and 8 are exemplary block diagrams of a channel estimator used in the BLE of FIG. 1; and

FIG. 9 is an exemplary block diagram of a noise power estimator used in the BLE of FIG. 1.

### DETAILED DESCRIPTION OF THE PREFERRED EMBODIMENTS

The features of the present invention may be incorporated into an IC or be configured in a circuit comprising a multitude of interconnecting components. The present invention is applicable to any wireless communication system including, but not limited to, the third generation partnership project (3GPP) frequency division duplex (FDD) HSDPA and non-HSDPA channels, time division duplex (TDD) HSDPA and non-HSDPA channels and CDMA2000 including 1xEV-DV and 1xEV-DO.

The following are symbols which are referred to throughout this application:

M: size of the middle of the block.

E: size of the edge of the block.

W: block size=M+2E.

L_{max:} maximum length of channel response vector in chips.

L: length of channel response vector that will be processed.

N: update rate of the channel response vector relative to the block rate (N=1 means the matrix R is inverted every W-chip block).

N_{r:} number of row blocks to compute before repeating.

N_{c:} number of column blocks to compute before repeating.

hₑ^{j}: channel response vector of length Lₘₐₓ or L corresponding to even samples from antenna # j.

hₒ^{j}: channel response vector of length Lₘₐₓ or L corresponding to odd samples from antenna # j.

rₑ^{j}: received vector of length W containing even samples from antenna # j.

rₒ^{j}: received vector of length W containing odd samples from antenna # j.

nₑ^{j}: received noise vector of length W containing even samples from antenna # j.

nₒ^{j}: received noise vector of length W containing odd samples from antenna # j.

s : vector of transmitted samples of length W−Lₘₐₓ+1 corresponding to length W vector of received samples that are being processed.

ŝ: vector of estimated received chips of length W−Lₘₐₓ+1.

H_{j,e}: channel response matrix of size W×(W−Lₘₐₓ+1) corresponding to even samples from antenna # j (having L non-zero elements per W-element column).

H_{j,o}: channel response matrix of size W×(W−Lₘₐₓ+1) corresponding to odd samples from antenna # j (having L non-zero elements per W-element column).

T_{c}: chip duration.

σ²: noise variance (actual or approximated) used in an MMSE solution.

The receiver in accordance with the present invention includes various techniques to reduce the receiver's computational complexity. Compared to a conventional Rake-based code division multiple access (CDMA) receiver, the receiver of the present invention provides a lower error probability and higher data throughput for a given set of communication channel conditions. Similarly, the receiver of the present invention provides an equivalent error probability under poorer channel conditions or at a greater distance between the transmitter and receiver.

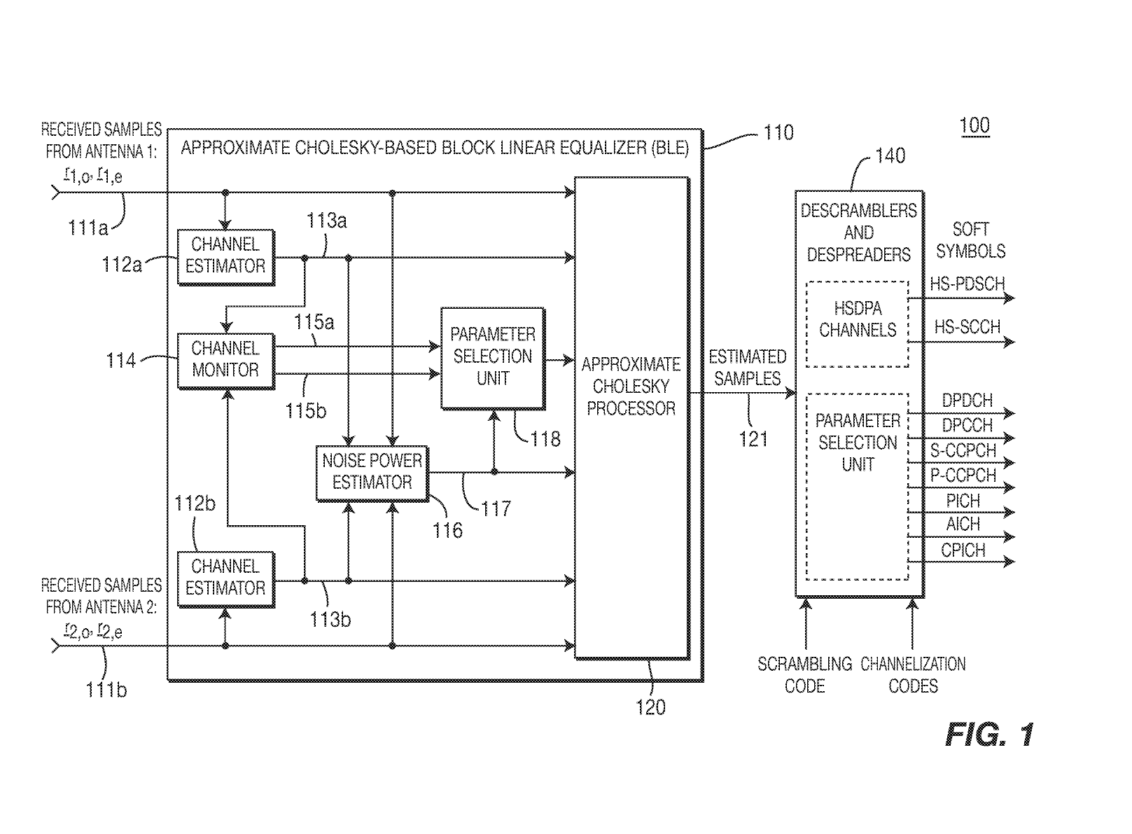

FIG. 1 is a block diagram of a receiver 100 in accordance with the present invention. The receiver 100 includes an approximate Cholesky-based BLE 110 and descramblers and despreaders 140. The receiver 100 may be used to process HSDPA channels, (such as high speed physical downlink shared channel (HS-PDSCH) and high speed shared control channel (HS-SCCH)), and/or non-HSDPA channels, (such as dedicated physical data channel (DPDCH), dedicated physical control channel (DPCCH), secondary common control physical channel (S-CCPCH), primary common control physical channel (P-CCPCH), paging indicator channel (PICH), acquisition indicator channel (AICH), and a common pilot channel (CPICH)).

The receiver 100 may use a 2× oversampling rate and two receive antennas. However, it should be noted that the receiver 100 may operate with any number of antennas at any sampling rate. One BLE may be used for both HSDPA and non-HSDPA channels, or alternatively, multiple BLEs may be used.

The BLE 110 includes channel estimators 112a, 112b, a channel monitor unit 114 (optional), a noise power estimator 116 (optional), a parameter selection unit 118 and an approximate Cholesky processor 120. The samples 111a, 111b generated from signals received via two receive antennas (not shown) are sent to the channel estimators 112a, 112b, respectively. The samples 111a, 111b are also sent to the noise power estimator 116 and the approximate Cholesky processor 120.

The channel estimators 112a, 112b generate channel estimate vectors hₑ¹, hₒ¹ 113a and hₑ², hₒ² 113b, respectively, based on the samples 111a, 111b. Each of the channel estimate vectors 113a, 113b has a length of Lₘₐₓ. The channel estimate vectors 113a, 113b are sent to the channel monitor unit 114 (or to the parameter selection unit 118 if the channel monitor unit 114 is not used), the noise power estimator 116 (if used) and the approximate Cholesky processor 120.

Based on the channel estimate vectors 113a, 113b, the channel monitor unit 114 may generate a first channel monitor signal 115a for truncated channel estimate vectors. The first channel monitor signal 115a identifies the truncated channel estimate vectors by specifying a vector length L, where L≦Lₘₐₓ. Various algorithms can be used to determine L. For example, when a threshold relative to the peak value in the channel estimate vectors 113a, 113b is set, L can be chosen to include elements that are above the threshold. Alternatively, the truncated channel estimate vector may be identified by a start point and a length L. For example, if the channel estimate vector 113a, 113b includes points 1 to Lₘₐₓ and there is only significant energy in points 4 to Lₘₐₓ−7, the channel monitor unit 114 may send the first channel monitor signal 115a to the parameter selection unit 118 to use only Lₘₐₓ−10 points spanning position 4 to Lₘₐₓ₋7 in the channel estimate vector 113a, 113b.

The channel estimators 112a, 112b may include a post-processing function that sets noise-only elements in the channel estimate vector 113a, 113b to zero. In such case, the channel monitor unit 114 may select L and the start point to simply include all non-zero values in the channel estimate vectors 113a, 113b.

The channel monitor unit 114 may also generate a second channel monitor signal 115b indicating the rate of change of the channel estimate vectors 113a, 113b. Generally, a wireless communication channel is a fading channel. For the fading channel, a coherence time and Doppler spread parameters may be calculated to determine how fast the channel is changing over time. The channel monitor unit 114 estimates the coherence time or Doppler spread based on the channel estimate vectors 113a, 113b and sends the second channel monitor signal 115b to the parameter selection unit 118. It should be noted that the description regarding the channel monitor unit 114 is given as an example and any variances are possible.

The noise power estimator 116 receives the samples 111a, 111b and channel estimate vectors 113a, 113b and generates a noise power estimate σ² required by an MMSE solution. The noise power estimator 116 may operate on the received samples 111a, 111b or the channel estimate vectors 113a, 113b, or both to generate the estimated σ² value.

The parameter selection unit 118 determines parameters 119 for the approximate Cholesky processor 120 based on the channel estimate 113a, 113b (or truncated channel estimate which is identified by the first channel monitor signal 115a) and/or the change of the channel condition indicated by the second channel monitor signal 115b . The parameters 119 may be selected to provide optimum demodulation performance, to reduce the computational complexity, or a combination of the two. The parameters 119 to be selected by the parameter selection unit 118 include, but are not limited to, an update rate (N), a block size (W) and an edge size (E) of the processing window block and the number of rows or columns, (Nr or Nc), to be computed before repeating for approximate Cholesky decomposition. The parameters, (i.e., N, W, E, Nr and Nc), are programmable according to channel conditions, such as a coherence time, Doppler spread, power saving parameters, or the like, and may be adapted during operation of the approximate Cholesky-based BLE 110 as the communication channel conditions change.

The update rate, N, indicates the interval at which the factorization is performed relative to the block rate, which will be explained in detail hereinafter. The factorization is only performed once every N frames (N≧1). The larger the N the less the average number of computations per frame. A value of N greater than one may be chosen, for example, if the channel coherence time is much greater than the time duration of an equalizer block.

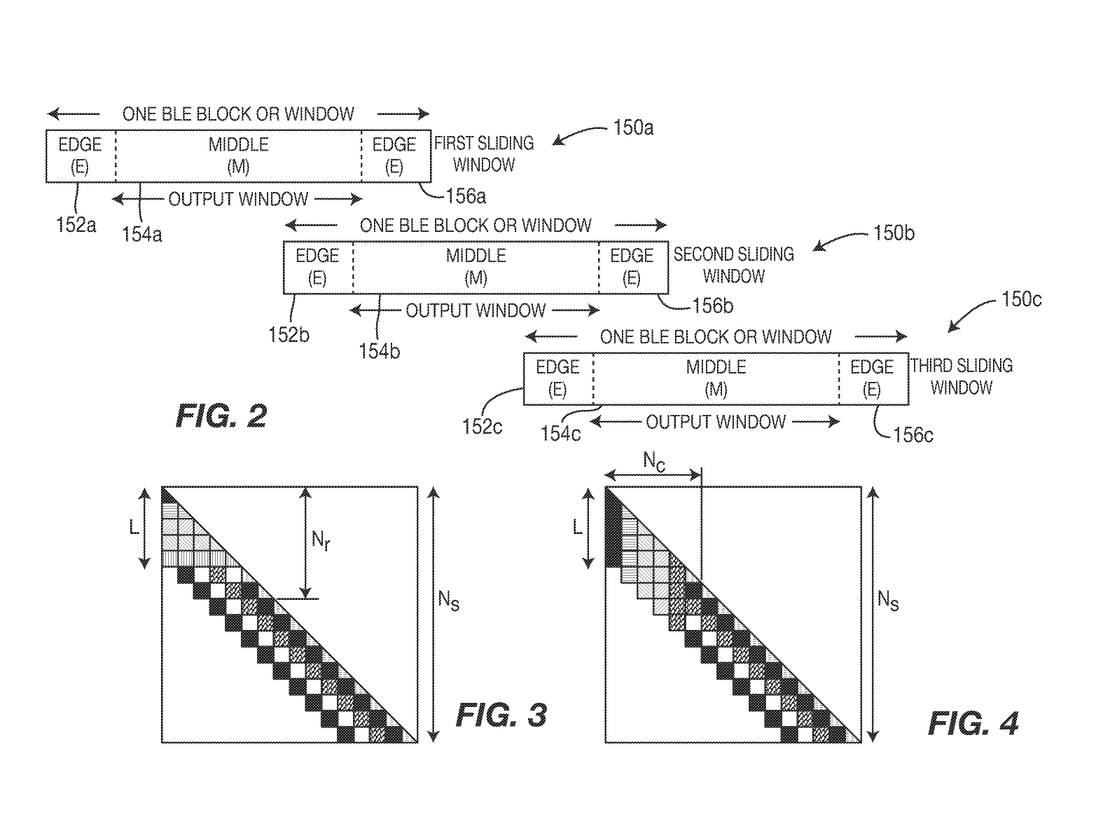

The approximate Cholesky-based BLE 110 operates on one block of samples at a time. Each block has a certain level of overlap with a preceding block and a subsequent block. FIG. 2 shows a sliding window operation used in the BLE 110. The BLE 110 processes one block 150a-150c of samples. Each block 150a-150c includes one middle portion 154a-154c and a leading edge 152a-152c and a tailing edge 156a-156c. Each leading edge, (e.g., 152b), overlaps with a middle portion, (e.g., 154a), of a previous window and a tailing edge, (e.g., 156b), overlaps with a middle portion, (e.g., 154c), of a subsequent window as shown in FIG. 2.

A large window size (W) provides more samples to generate a channel estimate. However, if the window size is too long as compared to the rate of change of the channel, the channel estimation may be poor. If the channel changes very slowly, using every block to compute a channel estimate may be unnecessary and the computational complexity can be reduced by computing the channel estimate less often. The present invention provides the ability to adapt the window size and the rate at which the channel estimates are computed.

The overlap between windows is necessary to accumulate enough multipath energy to adequately demodulate each block. For better demodulation performance, a larger edge (E) is advantageous, while for minimizing the number of computations, a shorter edge should be used. The present invention also provides the ability to adapt the edge size based on channel characteristics and an acceptable level of complexity. Typically, for HSDPA, W=256 and E=16 or W=512 and E=32 are selected. Other combinations of W and E are possible and adaptation over a wider range may also be used.

The number of rows (Nᵣ) or columns (N_{c}) to compute for approximate Cholesky decomposition, which will be explained in detail hereinafter, may be adapted. The smaller N_{c} or Nᵣ, the smaller the number of computations per frame. The value may be computed, for example, as a constant times the length of the channel response vector (L), (for example 2L).

The operation of the approximate Cholesky processor 120 is described hereinafter. Assuming that s is the transmitted signal vector sampled at a chip rate, the received samples can be written as follows:

$$[ \begin{matrix}{r}_{e} \\ {r}_{0}\end{matrix} ] = [ \begin{matrix}{H}_{e} \\ {H}_{0}\end{matrix} ] s + [ \begin{matrix}{n}_{e} \\ {n}_{0}\end{matrix} ] ; \qquad Equation ( 1 )$$

where nₑ and nₒ are noise vectors at the even and odd sampling positions, respectively. It is assumed that the noise variance (or power) is σₙ².

An MMSE solution for ŝ is given as follows:
ŝ=(Hₑ^{H}Hₑ+Hₒ^{H}Hₒ+σₙ²I)⁻¹(Hₑ^{H}rₑ+Hₒ^{H}rₒ); Equation (2)
where (•)^{H} is a complex conjugate transpose (or Hermitian) operation and I is a unit diagonal matrix.

A ZF solution for ŝ is given by omitting the σ² I terms as follows:
ŝ=(Hₑ^{H}Hₑ+Hₒ^{H}Hₒ)⁻¹(Hₑ^{H}rₑ+Hₒ^{H}rₒ); Equation (3)

For a two-antenna diversity receiver, the above development can be readily extended, where the superscripts and subscripts 1 and 2 denote the two receive antennas. Received samples via two receive antennas can be described as follows:

$$[ \begin{matrix}{r}_{e}^{1} \\ {r}_{o}^{1} \\ {r}_{e}^{2} \\ {r}_{o}^{2}\end{matrix} ] = [ \begin{matrix}{H}_{1 , e} \\ {H}_{1 , o} \\ {H}_{2 , e} \\ {H}_{2 , o}\end{matrix} ] s + [ \begin{matrix}{n}_{e}^{1} \\ {n}_{o}^{1} \\ {n}_{e}^{2} \\ {n}_{o}^{2}\end{matrix} ] . \qquad Equation ( 4 )$$

The MMSE solution for ŝ is given as follows:

$$\begin{matrix}\hat{s} = ( {H}_{1 , e}^{H} {H}_{1 , e} + {H}_{1 , o}^{H} {H}_{1 , o} + {H}_{2 , e}^{H} {H}_{2 , e} + \\ { {H}_{2 , o}^{H} {H}_{2 , o} + {σ}^{2} I )}^{- 1} ( {H}_{1 , e}^{H} {r}_{e}^{1} + {H}_{1 , o}^{H} {r}_{o}^{1} + \\ {H}_{2 , e}^{H} {r}_{e}^{2} + {H}_{2 , o}^{H} {r}_{o}^{2} ) \\ = {( {H}^{H} H + {σ}^{2} I )}^{- 1} ( {H}_{1 , e}^{H} {r}_{e}^{1} + {H}_{1 , o}^{H} {r}_{o}^{1} + \\ {H}_{2 , e}^{H} {r}_{e}^{2} + {H}_{2 , o}^{H} {r}_{o}^{2} )\end{matrix} \qquad Equation ( 5 )$$

The zero-forcing (ZF) solution for ŝ is given as follows:

$$\begin{matrix}\hat{s} = {( {H}_{1 , e}^{H} {H}_{1 , e} + {H}_{1 , o}^{H} {H}_{1 , o} + {H}_{2 , e}^{H} {H}_{2 , e} + {H}_{2 , o}^{H} {H}_{2 , o} )}^{- 1} \\ ( {H}_{1 , e}^{H} {r}_{e}^{1} + {H}_{1 , o}^{H} {r}_{o}^{1} + {H}_{2 , e}^{H} {r}_{e}^{2} + {H}_{2 , o}^{H} {r}_{o}^{2} ) \\ = {( {H}^{H} H )}^{- 1} ( {H}_{1 , e}^{H} {r}_{e}^{1} + {H}_{1 , o}^{H} {r}_{o}^{1} + {H}_{2 , e}^{H} {r}_{e}^{2} + {H}_{2 , o}^{H} {r}_{o}^{2} )\end{matrix} \qquad Equation ( 6 )$$

The formulation above is given for a two-times (2×) oversampled diversity receiver, which processes four streams of complex baseband received data. It should be noted that the above formulas are provided as an example, and a similar formulation can be presented for a single antenna, no oversampling (1×) or an arbitrary oversampling rate and any number of antennas. The teachings of the present invention are equally applicable to the various sets of parameters.

Both the MMSE and ZF solutions require a matrix inversion. The matrix to be inverted is denoted as R. As shown below, the matrix R is a banded block-Toeplitz matrix and has at most 2L+1 non-zero entries per row or column.

$$R = [ \begin{matrix}{R}_{0} & {R}_{1} & {R}_{2} & {R}_{3} & {R}_{L - 1} & 0 & 0 & 0 & 0 & 0 & 0 & 0 \\ {R}_{1}^{H} & {R}_{0} & {R}_{1} & {R}_{2} & {R}_{3} & {R}_{L - 1} & 0 & 0 & 0 & 0 & 0 & 0 \\ {R}_{2}^{H} & {R}_{1}^{H} & {R}_{0} & {R}_{1} & {R}_{2} & {R}_{3} & {R}_{L - 1} & 0 & 0 & 0 & 0 & 0 \\ {R}_{3}^{H} & {R}_{2}^{H} & {R}_{1}^{H} & {R}_{0} & {R}_{1} & {R}_{2} & {R}_{3} & {R}_{L - 1} & 0 & 0 & 0 & 0 \\ {R}_{L - 1}^{H} & {R}_{3}^{H} & {R}_{2}^{H} & {R}_{1}^{H} & {R}_{0} & {R}_{1} & {R}_{2} & {R}_{3} & {R}_{L - 1} & 0 & 0 & 0 \\ 0 & {R}_{L - 1}^{H} & {R}_{3}^{H} & {R}_{2}^{H} & {R}_{1}^{H} & {R}_{0} & {R}_{1} & {R}_{2} & {R}_{3} & {R}_{L - 1} & 0 & 0 \\ 0 & 0 & {R}_{L - 1}^{H} & {R}_{3}^{H} & {R}_{2}^{H} & {R}_{1}^{H} & {R}_{0} & {R}_{1} & {R}_{2} & {R}_{3} & {R}_{L - 1} & 0 \\ 0 & 0 & 0 & {R}_{L - 1}^{H} & {R}_{3}^{H} & {R}_{2}^{H} & {R}_{1}^{H} & {R}_{0} & {R}_{1} & {R}_{2} & {R}_{3} & {R}_{L - 1} \\ 0 & 0 & 0 & 0 & {R}_{L - 1}^{H} & {R}_{3}^{H} & {R}_{2}^{H} & {R}_{1}^{H} & {R}_{0} & {R}_{1} & {R}_{2} & {R}_{3} \\ 0 & 0 & 0 & 0 & 0 & {R}_{L - 1}^{H} & {R}_{3}^{H} & {R}_{2}^{H} & {R}_{1}^{H} & {R}_{0} & {R}_{1} & {R}_{2} \\ 0 & 0 & 0 & 0 & 0 & 0 & {R}_{L - 1}^{H} & {R}_{3}^{H} & {R}_{2}^{H} & {R}_{1}^{H} & {R}_{0} & {R}_{1} \\ 0 & 0 & 0 & 0 & 0 & 0 & 0 & {R}_{L - 1}^{H} & {R}_{3}^{H} & {R}_{2}^{H} & {R}_{1}^{H} & {R}_{0}\end{matrix} ] \qquad Equation ( 7 )$$

The Cholesky decomposition factors R into the product of a lower triangular matrix, G, and its conjugate transpose, G^{H}, such that R=GG^{H}. An example of a 12×12 G matrix is shown below.

$$G = [ \begin{matrix}{G}_{11} & 0 & 0 & 0 & 0 & 0 & 0 & 0 & 0 & 0 & 0 & 0 \\ {G}_{21} & {G}_{22} & 0 & 0 & 0 & 0 & 0 & 0 & 0 & 0 & 0 & 0 \\ {G}_{31} & {G}_{32} & {G}_{33} & 0 & 0 & 0 & 0 & 0 & 0 & 0 & 0 & 0 \\ {G}_{41} & {G}_{42} & {G}_{43} & {G}_{44} & 0 & 0 & 0 & 0 & 0 & 0 & 0 & 0 \\ {G}_{51} & {G}_{52} & {G}_{53} & {G}_{54} & {G}_{55} & 0 & 0 & 0 & 0 & 0 & 0 & 0 \\ 0 & {G}_{62} & {G}_{63} & {G}_{64} & {G}_{65} & {G}_{66} & 0 & 0 & 0 & 0 & 0 & 0 \\ 0 & 0 & {G}_{73} & {G}_{74} & {G}_{75} & {G}_{76} & {G}_{77} & 0 & 0 & 0 & 0 & 0 \\ 0 & 0 & 0 & {G}_{84} & {G}_{85} & {G}_{86} & {G}_{87} & {G}_{88} & 0 & 0 & 0 & 0 \\ 0 & 0 & 0 & 0 & {G}_{95} & {G}_{96} & {G}_{97} & {G}_{98} & {G}_{99} & 0 & 0 & 0 \\ 0 & 0 & 0 & 0 & 0 & {G}_{10 , 6} & {G}_{10 , 7} & {G}_{10 , 8} & {G}_{10 , 9} & {G}_{10 , 10} & 0 & 0 \\ 0 & 0 & 0 & 0 & 0 & 0 & {G}_{11 , 7} & {G}_{11 , 8} & {G}_{11 , 9} & {G}_{11 , 10} & {G}_{11 , 11} & 0 \\ 0 & 0 & 0 & 0 & 0 & 0 & 0 & {G}_{12 , 8} & {G}_{12 , 9} & {G}_{12 , 10} & {G}_{12 , 11} & {G}_{12 , 12}\end{matrix} ] \qquad Equation ( 8 )$$

The approximate Cholesky decomposition reduces the computational complexity by repeating various elements rather than computing every Gᵢⱼ. For example, in the above 12×12 example, all rows up to nine are computed and rows 10, 11, and 12 are filled in by shifting and repeating the elements in row 9 as follows:

$$\tilde{G} = [ \begin{matrix}{\tilde{G}}_{11} & 0 & 0 & 0 & 0 & 0 & 0 & 0 & 0 & 0 & 0 & 0 \\ {\tilde{G}}_{21} & {\tilde{G}}_{22} & 0 & 0 & 0 & 0 & 0 & 0 & 0 & 0 & 0 & 0 \\ {\tilde{G}}_{31} & {\tilde{G}}_{32} & {\tilde{G}}_{33} & 0 & 0 & 0 & 0 & 0 & 0 & 0 & 0 & 0 \\ {\tilde{G}}_{41} & {\tilde{G}}_{42} & {\tilde{G}}_{43} & {\tilde{G}}_{44} & 0 & 0 & 0 & 0 & 0 & 0 & 0 & 0 \\ {\tilde{G}}_{51} & {\tilde{G}}_{52} & {\tilde{G}}_{53} & {\tilde{G}}_{54} & {\tilde{G}}_{55} & 0 & 0 & 0 & 0 & 0 & 0 & 0 \\ 0 & {\tilde{G}}_{62} & {\tilde{G}}_{63} & {\tilde{G}}_{64} & {\tilde{G}}_{65} & {\tilde{G}}_{55} & 0 & 0 & 0 & 0 & 0 & 0 \\ 0 & 0 & {\tilde{G}}_{73} & {\tilde{G}}_{74} & {\tilde{G}}_{75} & {\tilde{G}}_{65} & {\tilde{G}}_{55} & 0 & 0 & 0 & 0 & 0 \\ 0 & 0 & 0 & {\tilde{G}}_{84} & {\tilde{G}}_{85} & {\tilde{G}}_{75} & {\tilde{G}}_{65} & {\tilde{G}}_{55} & 0 & 0 & 0 & 0 \\ 0 & 0 & 0 & 0 & {\tilde{G}}_{95} & {\tilde{G}}_{85} & {\tilde{G}}_{75} & {\tilde{G}}_{65} & {\tilde{G}}_{55} & 0 & 0 & 0 \\ 0 & 0 & 0 & 0 & 0 & {\tilde{G}}_{95} & {\tilde{G}}_{85} & {\tilde{G}}_{75} & {\tilde{G}}_{65} & {\tilde{G}}_{55} & 0 & 0 \\ 0 & 0 & 0 & 0 & 0 & 0 & {\tilde{G}}_{95} & {\tilde{G}}_{85} & {\tilde{G}}_{75} & {\tilde{G}}_{65} & {\tilde{G}}_{55} & 0 \\ 0 & 0 & 0 & 0 & 0 & 0 & 0 & {\tilde{G}}_{95} & {\tilde{G}}_{85} & {\tilde{G}}_{75} & {\tilde{G}}_{65} & {\tilde{G}}_{55}\end{matrix} ] \qquad Equation ( 9 )$$

The approximation may be implemented by repeating either rows or columns. When the rows are repeated, among a total of Nₛ rows, Nᵣ rows are computed and the last Nₛ-Nᵣ rows use the elements in row Nᵣ, as shown in FIG. 3. Alternatively, when the columns are repeated, among a total of Nₛ columns, N_{c} columns are computed and the remaining Nₛ-N_{c} columns are filled using the elements in column N_{c} , as shown in FIG. 4. Other methods of repeating entries, such as along a diagonal, may also be used.

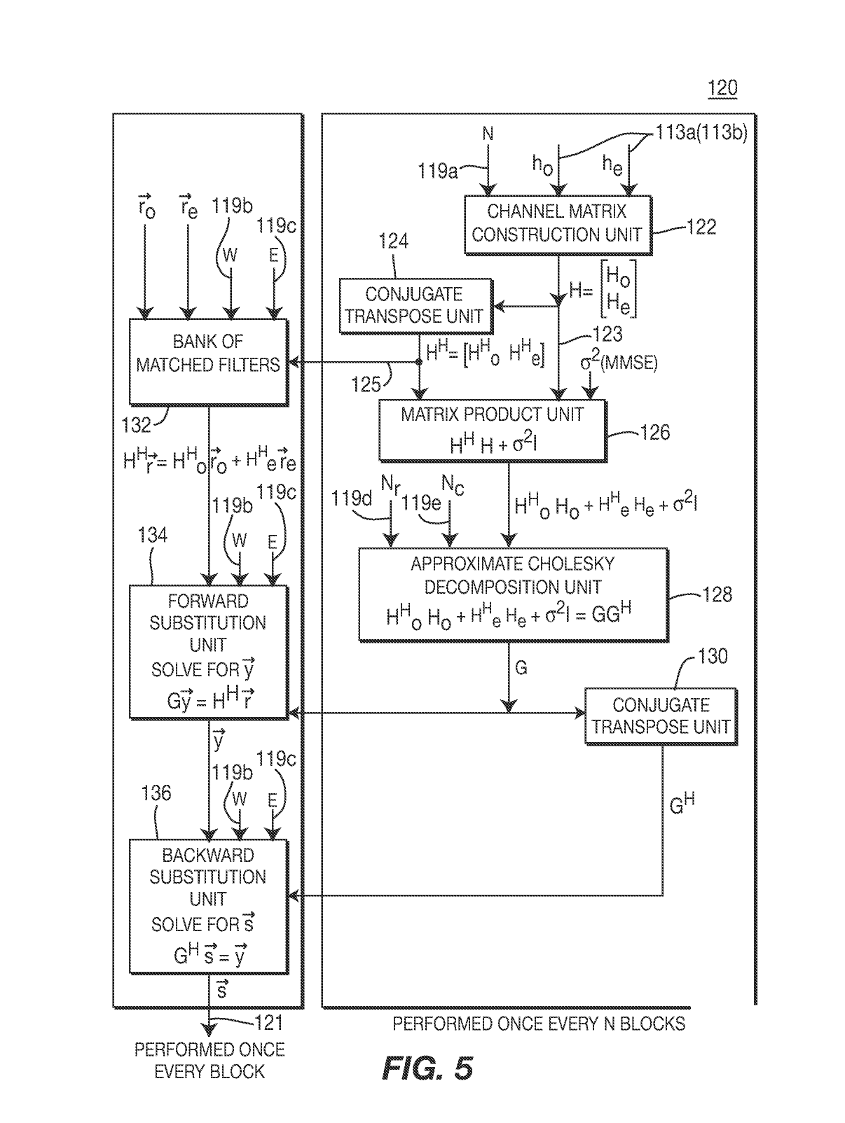

FIG. 5 is a block diagram of an approximate Cholesky processor 120 for 2×oversampling with onₑ receive antenna. The approximate Cholesky processor 120 includes a channel matrix construction unit 122, a first conjugate transpose unit 124, a matrix product unit 126, an approximate Cholesky decomposition unit 128, a second conjugate transpose unit 130, a bank of matched filters 132, a forward substitution unit 134 and a backward substitution unit 136

The channel matrix construction unit 122 receives a channel estimate vector, (i.e., a channel impulse response vector), generated from 2× oversampled received samples and a parameter N 119a, and constructs a channel matrix H′ once every N blocks. The channel matrix H′ is written as follows:

$${H}^{′} = \vert \begin{matrix}{h}_{0} & & & \\ {h}_{1} & {h}_{0} & & \\ {h}_{2} & {h}_{1} & & \\ ⋮ & {h}_{2} & & {h}_{0} \\ {h}_{2 L - 1} & ⋮ & ⋰ & {h}_{1} \\ & {h}_{2 L - 1} & ⋰ & {h}_{2} \\ & & ⋰ & ⋮ \\ & & & {h}_{2 L - 1}\end{matrix} \vert ; \qquad Equation ( 10 )$$

where L is the channel impulse response length in chips and H′ has 2W rows. The channel matrix H′ is separated into an even matrix and an odd matrix as follows:

$$\begin{matrix}{H}_{e} = \vert \begin{matrix}{h}_{0} & & & \\ {h}_{2} & {h}_{0} & & \\ {h}_{4} & {h}_{2} & & \\ ⋮ & {h}_{4} & & {h}_{0} \\ {h}_{2 L - 2} & ⋮ & ⋰ & {h}_{2} \\ & {h}_{2 L - 2} & ⋰ & {h}_{4} \\ & & ⋰ & ⋮ \\ & & & {h}_{2 L - 2}\end{matrix} \vert , \\ and & Equation ( 11 ) \\ {H}_{o} = \vert \begin{matrix}{h}_{1} & & & \\ {h}_{3} & {h}_{1} & & \\ {h}_{5} & {h}_{3} & & \\ ⋮ & {h}_{5} & & {h}_{1} \\ {h}_{2 L - 1} & ⋮ & ⋰ & {h}_{3} \\ & {h}_{2 L - 1} & ⋰ & {h}_{5} \\ & & ⋰ & ⋮ \\ & & & {h}_{2 L - 1}\end{matrix} \vert . & Equation ( 12 )\end{matrix}$$

The channel matrix construction unit 122 then outputs a channel matrix H=[HₒHₑ]^{T} to the first conjugate transpose unit 124 and the matrix product unit 126. The first conjugate transpose unit 124 generates a conjugate transpose of the channel matrix H and outputs the matrix H^{H} to the bank of matched filters 132 and the matrix product unit 126.

The matrix product unit 126 performs a matrix product operation and outputs Hₑ^{H}Hₑ+Hₒ^{H}Hₒ+σₙ²I ,(i.e., a matrix R) for an MMSE solution, (alternatively, Hₑ^{H}Hₑ+Hₒ^{H}Hₒ for a ZF solution), to the approximate Cholesky decomposition unit 128. The approximate Cholesky decomposition unit 128 receives a parameter Nᵣ119d, (or N_{c} 119e), and performs approximate Cholesky decomposition on the matrix R to factor the matrix R into G and G^{H}. The approximate Cholesky decomposition may be implemented by repeating rows, in which case the first Nᵣ rows are computed and the values in the row Nᵣ is repeated to fill out the matrix. Alternatively, the approximate Cholesky decomposition may be implemented by repeating columns, in which case the first N_{c} columns are computed and the values in the column N_{c} are repeated to fill out the matrix. The approximate Cholesky decomposition unit 128 outputs the matrix G to the forward substitution unit 134 and the second conjugate transpose unit 130. The second conjugate transpose unit 130 generates rates G^{H} and outputs it to the backward substitution unit 136.

The channel matrix construction unit 122, the first conjugate transpose unit 124, the matrix product unit 126, the approximate Cholesky decomposition unit 128 and the second conjugate transpose unit 130 operate once every N blocks, while the bank of matched filters 132, the forward substitution unit 134 and the backward substitution unit 136 operate once every block of samples. N 119a is an update rate determined by the parameter selection unit 118.

The bank of matched filters 132 receives even and odd sample vectors, rₑ=[r₀, r₂, . . . , r_{2W-2}]^{T} and r₀=[r₁, r₃, . . . , r_{2W-1}]^{T} and parameters W 119b and E 119c. Each of the vectors include W samples and are constructed using overlapping sliding windows with E leading samples, M middle samples, and E trailing samples as shown in FIG. 2. The bank of matched filters 132 multiples the even and odd sample vectors with the matrix H^{H} received from the first conjugate transpose unit 124. The bank of matched filters 132 then outputs H^{H} r to the forward substitution unit 134. The parameters W 119b and E 119c are also fed to the forward substitution unit 134 and the backward substitution unit 136. The forward substitution unit 134 solves the matrix equation G y=H^{H} r for y and outputs y to the backward substitution unit 136. The backward substitution unit 136 solves G ŝ=y for ŝ and outputs ŝ as equalized samples 121.

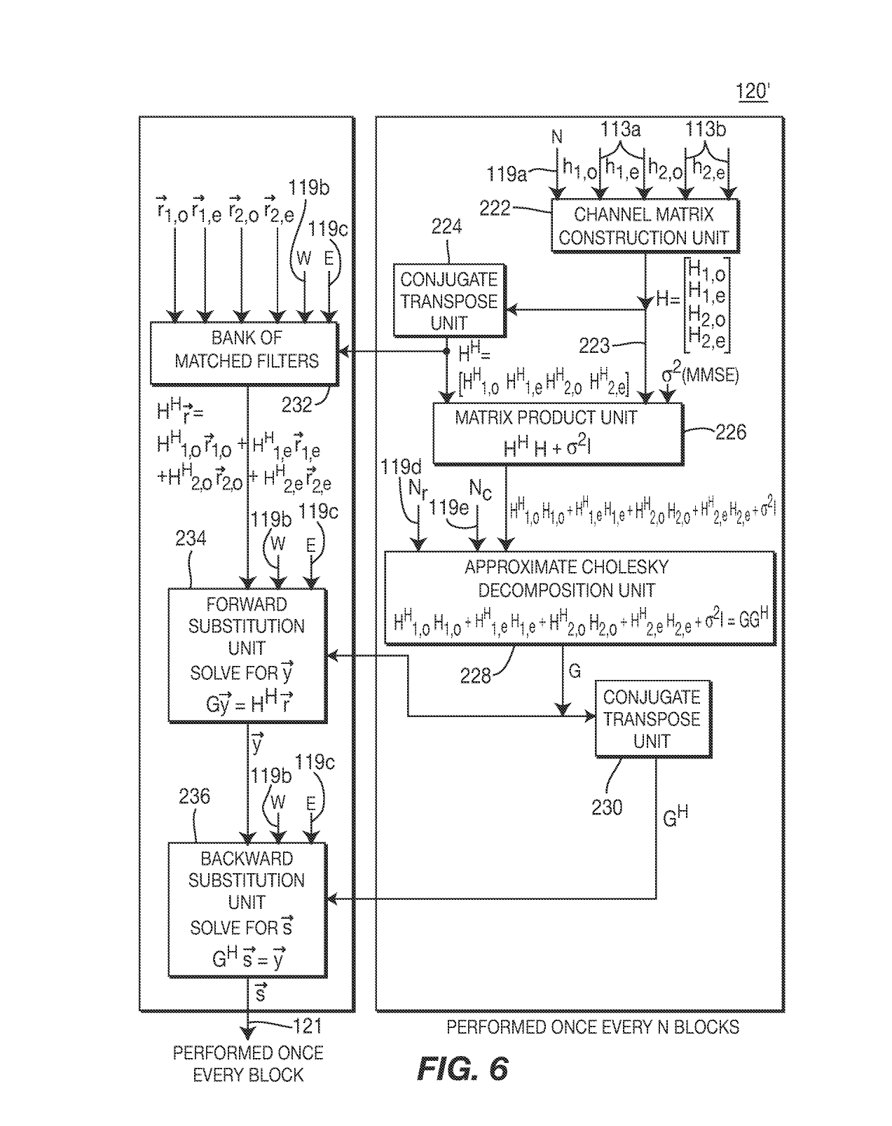

FIG. 6 is another exemplary block diagram of an approximate Cholesky processor 120′ used in the BLE 110 of FIG. 1. The approximate Cholesky processor 120′ includes a channel matrix construction unit 222, a first conjugate transpose unit 224, a matrix product unit 226, an approximate Cholesky decomposition unit 228, a second conjugate transpose unit 230, a bank of matched filters 232, a forward substitution unit 234 and a backward substitution unit 236.

The channel matrix construction unit 222 receives a channel estimate vector, (i.e., a channel impulse response vector), generates rated from 2× oversampled received samples from two receive antennas and a parameter N 119a. The channel matrix construction unit 222 outputs a channel matrix H=[H_{1,o}H_{1,e}H_{2,o}H_{2,e}]^{T} to the first conjugate transpose unit 224 and the matrix product unit 226 once every N blocks. The first conjugate transpose unit 224 generates rates a conjugate transpose of the channel matrix H and outputs the matrix H^{H} to the bank of matched filters 232 and the matrix product unit 226.

The matrix product unit 226 performs matrix product operation and outputs H_{1,o}^{H}H_{1,o}+H_{1,e}^{H}H_{1,e}+H_{2,o}^{H}H_{2,o}+H_{2,e}^{H}H_{2,e}94 ₙ²I, (i.e., a matrix R) for an MMSE solution, (alternatively, H_{1,o}^{H}H_{1,o}+H_{1,e}^{H}H_{1,e}+H_{2,o}^{H}H_{2,o}+H_{2,e}^{H}H_{2,e} for a ZF solution), to the approximate Cholesky decomposition unit 228. The approximate Cholesky decomposition unit 228 receives a parameter Nᵣ 119d, (or N_{c} 119e), and performs approximate Cholesky decomposition on the matrix R to factor the matrix R into G and G^{H} . The approximate Cholesky decomposition may be implemented by repeating rows, in which case the first Nᵣ rows are computed and the values in the row Nᵣ are repeated to fill out the matrix. Alternatively, the approximate Cholesky decomposition may be implemented by repeating columns, in which case the first N_{c} columns are computed and the values in the column N_{c} are repeated to fill out the matrix. The approximate Cholesky decomposition unit 228 outputs the matrix G to the forward substitution unit 234 and the second conjugate transpose unit 230. The second conjugate transpose unit 230 generates rates G^{H} and outputs it to the backward substitution unit 236.

The channel matrix construction unit 222, the first conjugate transpose unit 224, the matrix product unit 226, the approximate Cholesky decomposition unit 228 and the second conjugate transpose unit 230 operate once every N blocks, while the bank of matched filters 232 the forward substitution unit 234 and the backward substitution unit 236 operate once every block of samples.

The bank of matched filters 232 receives even and odd sample vectors, r_{1,o},r_{1,e},r_{2,o},r_{2,e} and parameters W 119b and E 119c. Each sample vector is constructed using an overlapped sliding window. The back of matched filters 232 multiples the even and odd sample vectors with the matrix H^{H} received from the first conjugate transpose unit 224. The bank of matched filters 232 then outputs H^{H} r to the forward substitution unit 234. The parameters W 119b and E 119c are also fed to the forward substitution unit 134 and the backward substitution unit 136. The forward substitution unit 234 solves the matrix equation G y=H^{H} r for y and outputs y to the backward substitution unit 236.The backward substitution unit 236 solves G ŝ=y for ŝ and outputs ŝ as equalized samples 121.

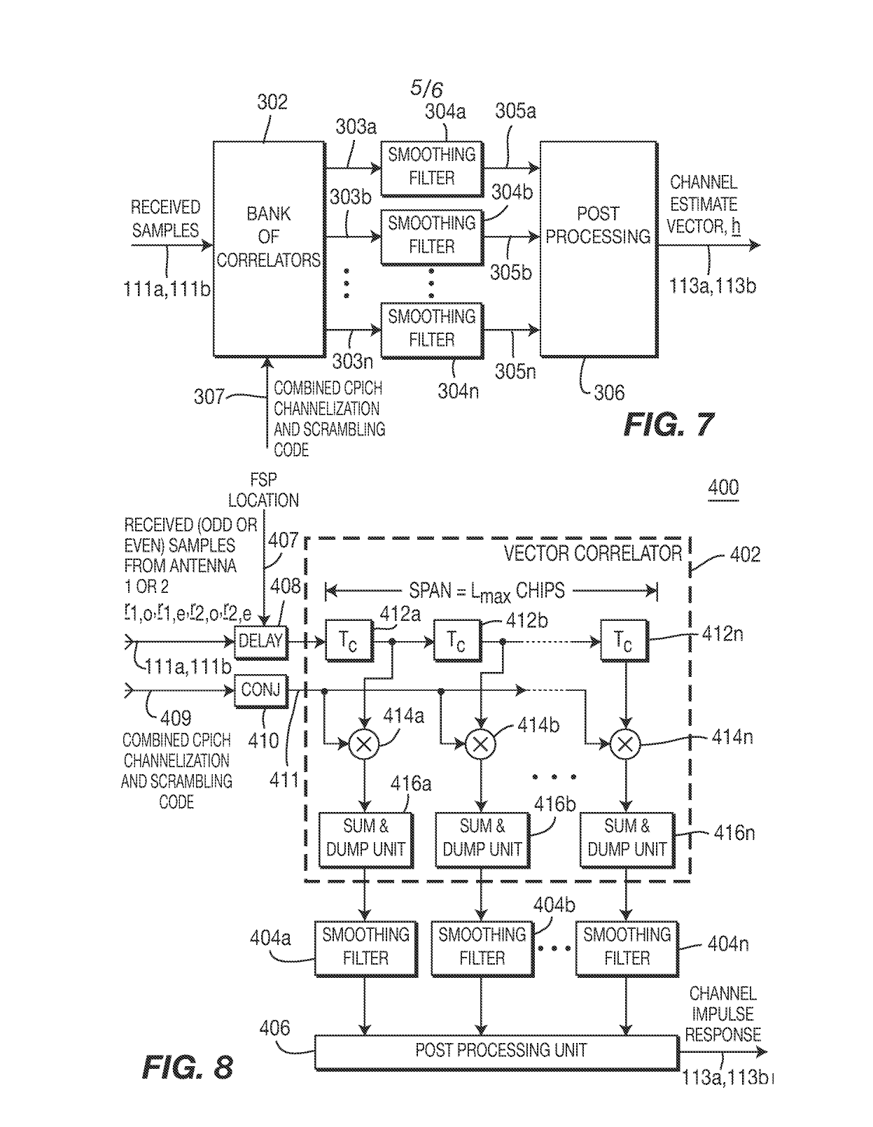

FIG. 7 is an exemplary block diagram of a channel estimator, such as channel estimators 112a and 112b used in the BLE 110 of FIG. 1. Each of the channel estimators 112a and 112b comprises a bank of correlators 302, smoothing filters 304a-304n and preferably a post processing unit 306. Received samples 111a, 111b are correlated with a combined channelization/scrambling code for the common pilot channel (CPICH) 307 (either primary CPICH (P-CPICH) or secondary CPICH (S-CPICH)) by the bank of correlators 302. The correlation results 303a-303n are filtered by the smoothing filters 304a-304n and the outputs 305a-305n of the smoothing filters 304a-304n are processed by the post processing unit 306. The post processing unit 306 outputs channel estimate vectors, h, 113a, 113b.

The post processing unit 306 eliminates or minimizes the effect of noisy samples in a channel estimate vector. The post-processing unit 306 may set all elements with a magnitude below a threshold to zero. The threshold may be computed as a constant (less than 1) times the magnitude of the largest element in the channel estimate vector. Alternatively, the threshold may be computed as a constant (greater than 1) times an average magnitude (or some approximation to the average magnitude) of all elements in the channel estimate vector. Alternatively, two thresholds may be computed using both methods and the final threshold may be selected as the larger or smaller of the two values.

FIG. 8 is another exemplary block diagram of a channel estimator, such as the channel estimators 112a and 112b used in the BLE 110 of FIG. 1. Each of the channel estimators 112a and 112b includes a vector correlator 402, smoothing filters 404a-404n and a post-processing unit 406. The vector correlator 402 includes a plurality of delay units 412a-412n, multipliers 414a-414n and sum and dump processors 416a-416n. The vector correlator 402 spans Lₘₐₓ chips. A typical value of Lₘₐₓ for HSDPA applications is 20 chips. Received samples 111a, 111b are delayed by a delay unit 408 in accordance with a first significant path (FSP) location signal 407 before entering into the vector correlator 402. A conjugate 411 of a combined CPICH channelization and scrambling code 409 is generates rated by a conjugate unit 410. The received samples 111a, 111b are then forwarded to the delay units 412a-412n chip by chip and delayed. Each of the received samples delayed by the delay units 412a-412n is then multiplied to the conjugate 411 of the combined CPICH channelization and scrambling code by the multipliers 414a-414n. The multiplication results are summed over K samples by the sum and dump processors 416a-416n. The outputs from the sum and dump processors 416a-416n are processed by the smoothing filters 404a-404n. The smoothing filters 404a-404n may be block averagers, finite impulse response (FIR) filters or infinite impulse response (IIR) filters. The outputs of the smoothing filters 404a-404n are fed to the post-processing unit 406 which outputs a channel impulse response 113a, 113b . The post-processing unit 406 eliminates or minimizes the effect of noisy samples in the channel estimate vector 113a, 113b .

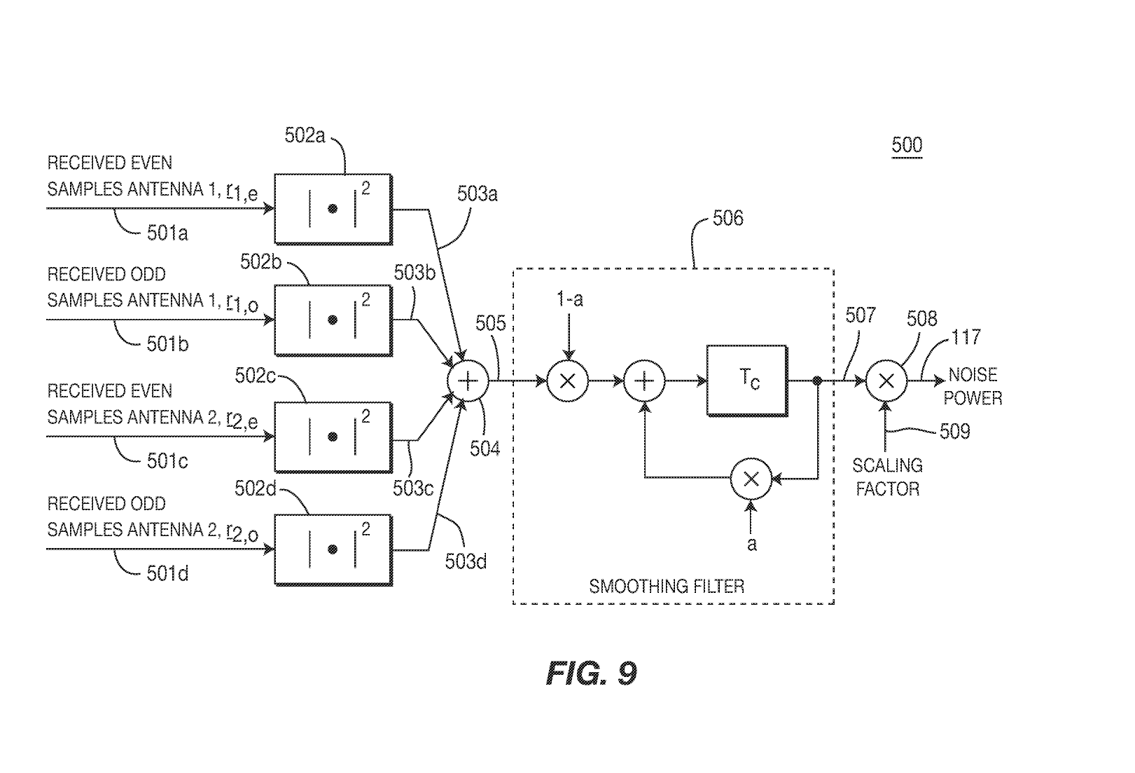

FIG. 9 is an exemplary block diagram of a noise power estimator 116 used in the BLE 110 of FIG. 1. The noise power estimator 116 includes a plurality of magnitude calculation units 502a-502d, a summer 504, a smoothing filter 506 and a scaling unit 508. Each of the magnitude calculation units 502a-502d calculates the magnitude (or approximate magnitude) of even and odd samples 501a-501d from two receive antennas, respectively. The magnitude values 503a-503d are then summed by the summer 504. The summed magnitude 505 is applied to the smoothing filter 506, and the filtered value 507 is then multiplied with a scaling factor 509 by the scaling unit 508 to generates rate the noise power value 117.

Although the features and elements of the present invention are described in the preferred embodiments in particular combinations, each feature or element can be used alone without the other features and elements of the preferred embodiments or in various combinations with or without other features and elements of the present invention.

What is claimed is:

1. A block linear equalizer (BLE) for performing block linear equalization on a block of samples using an approximate Cholesky decomposition, the BLE comprising:
a channel estimator for generates rating a channel estimate vector from received samples;
a parameter selection unit for selecting parameters for approximate Cholesky decomposition based on the channel estimate; and
an approximate Cholesky processor for performing block linear equalization on the received samples using approximate Cholesky decomposition and the selected parameters.

2. The BLE of claim 1 wherein the block linear equalization is performed based on zero forcing (ZF) solution.

3. The BLE of claim 1 further comprising a noise power estimator for estimating a noise power.

4. The BLE of claim 3 wherein the block linear equalization is performed based on minimum mean square error (MMSE) solution.

5. The BLE of claim 1 further comprises a channel monitor unit for generates rating a first channel monitor signal for identifying a truncated channel estimate vector, whereby the parameter selection unit selects the parameters based on the truncated channel estimate.

6. The BLE of claim 5 wherein the channel monitor unit generates rates the first channel monitor signal by specifying a vector length L.

7. The BLE of claim 6 wherein the channel monitor unit determines the vector length by comparing each element in the channel estimate vector with a threshold which is set relative to a peak value in the channel estimate vector.

8. The BLE of claim 6 wherein the channel monitor unit generates rates the first channel monitor signal by identifying a start point and a length.

9. The BLE of claim 5 wherein the channel estimator is configured to perform post-processing on the generates rated channel estimate vector to remove noise-only elements.

10. The BLE of claim 9 wherein the channel monitor unit selects a vector length and a start point to include all non-zero values in the post-processed channel estimate vector.

11. The BLE of claim 5 wherein the channel monitor unit further generates rates a second channel monitor signal indicating a change of channel condition, whereby the parameter selection unit selects the parameters based on the change of channel condition.

12. The BLE of claim 11 wherein the channel monitor unit generates rates the second channel monitor signal indicating the rate of change of the channel estimate vector.

13. The BLE of claim 12 wherein the channel monitor unit calculates the rate by determining a coherence time and Doppler spread on the channel.

14. The BLE of claim 1 wherein the approximate Cholesky processor comprises:
a channel matrix construction unit for generates rating a channel matrix H from the channel estimate vector;
a first conjugate transpose unit for generates rating a Hermitian transpose of the channel matrix H^{H};
a matrix product unit for performing matrix product of the channel matrix and the Hermitian transpose of the channel matrix to generates rating a R matrix;
an approximate Cholesky decomposition unit for factoring the R matrix into G matrix and G^{H} matrix;
a second conjugate transpose unit for generates rating a Hermitian transpose of the G matrix;
a bank of matched filters for multiplying received samples r and the Hermitian transpose of the channel matrix H^{H};
a forward substitution unit for solving a matrix equation G y=H^{H} r for y; and
a backward substitution unit for solving a matrix equation G ŝ=y for ŝ to generates rate equalized samples.

15. The BLE of claim 14 wherein the parameter selection unit determines an update rate and the matrix product unit, the approximate Cholesky decomposition unit and the second conjugate transpose unit operate at the update rate.

16. The BLE of claim 14 wherein the approximate Cholesky decomposition unit generates rates the matrix G by computing only a first portion of data in the matrix G and filling remaining data by repeating certain data in the matrix G.

17. The BLE of claim 16 wherein the approximate Cholesky decomposition unit computes first Nr rows or Nc columns and fills remaining data by repeating data in Nr or Nc column.

18. The BLE of claim 17 wherein the parameter selection unit determines the Nr and Nc for the approximate Cholesky decomposition unit.

19. The BLE of claim 1 wherein each block of samples comprise a middle portion and two edges, whereby the edges overlap to a middle portion of a preceding block and a subsequent block, respectively.

20. The BLE of claim 19 wherein the parameter selection unit determines a size of the block and the edges.

21. The BLE of claim 1 wherein the parameter selection unit adaptively adjusts the parameters based on coherence time, Doppler spread and power saving parameters.

22. The BLE of claim 1 wherein the channel estimator comprises:
a bank of correlators for correlating received samples with a known code sequence;
smoothing filters for filtering correlation results from the bank of correlators; and
a post processing unit for removing noise-only elements from output of the smoothing filters.

23. The BLE of claim 22 wherein the known code sequence is a common pilot channel (CPICH) code sequence.

24. The BLE of claim 22 wherein the post-processing unit sets all elements with a magnitude below a threshold to zero.

25. The BLE of claim 24 wherein the threshold is computed as a constant times the magnitude of the largest element in the channel estimate vector.

26. The BLE of claim 24 wherein the threshold is computed as a constant times an average magnitude of all elements in the channel estimate vector.

27. The BLE of claim 24 wherein the threshold is selected one of a constant times the magnitude of the largest element in the channel estimate vector and a constant times an average magnitude of all elements in the channel estimate vector.

28. The BLE of claim 1 wherein the channel estimator comprises:
a vector correlator for performing a vector correlation of the received samples with a scrambling code conjugate;
smoothing filters for filtering correlation results of the vector correlator; and
a post-processing unit for removing noise-only elements from output of the smoothing filters.

29. The BLE of claim 3 wherein the noise power estimator comprises:
magnitude calculation units for calculating magnitude of the received samples;
a smoothing filter for filtering magnitude values calculated by the magnitude calculation units; and
a scaling unit for multiplying a scaling factor to output of the smoothing filter.

30. A method for generates rating equalized samples by a block linear equalizer (BLE) operating on a block of received samples at a time and using an approximate Cholesky decomposition, the method comprising:
generates rating a channel estimate vector from received samples;
selecting parameters for approximate Cholesky decomposition based on the channel estimate; and
performing block linear equalization on the received samples using approximate Cholesky decomposition and the selected parameters.

31. The method of claim 30 wherein the block linear equalization is performed based on zero forcing (ZF) solution.

32. The method of claim 30 further comprising:
estimating a noise power, whereby the block linear equalization is performed based on minimum mean square error (MMSE) solution.

33. The method of claim 30 further comprising generates rating a first channel monitor signal for identifying a truncated channel estimate vector, whereby the parameters are selected based on the truncated channel estimate vector.

34. The method of claim 33 wherein the first channel monitor signal specifies a vector length L for a truncated channel estimate vector.

35. The method of claim 34 wherein the vector length is determined by comparing each element in the channel estimate vector with a threshold which is determined relative to a peak value in the channel estimate vector.

36. The method of claim 34 wherein the first channel monitor signal identifies a start point and a length of the truncated channel estimate vector.

37. The method of claim 34 further comprising generates rating a second channel monitor signal indicating a change of channel condition, whereby the parameters are selected based on the change of channel condition.

38. The method of claim 37 wherein the second channel monitor signal indicates a rate of change of the channel estimate vector.

39. The method of claim 38 wherein the rate is calculated by determining a coherence time and Doppler spread on the channel.

40. The method of claim 30 wherein the step of block linear equalization comprises:
generates rating a channel matrix H from the channel estimate vector;
generates rating a Hermitian transpose of the channel matrix H^{H};
performing matrix product of the channel matrix and the Hermitian transpose of the channel matrix to generates rating an R matrix;
factoring the R matrix into G matrix and G^{H} matrix;
generates rating a Hermitian transpose of the G matrix;
multiplying the received samples r and the Hermitian transpose of the channel matrix H^{H};
solving a matrix equation G y=H^{H}r for y; and
solving a matrix equation G ŝ=y for ŝ to generates rate equalized samples.

41. The method of claim 40 wherein the parameter includes an update rate, whereby the steps of performing matrix product, factoring the R matrix and generates rating a Hermitian transpose of the G matrix are performed at the update rate.

42. The method of claim 40 wherein the matrix G is generates rated by computing only a first portion of data in the matrix G and filling remaining data by repeating certain data in the matrix G.

43. The method of claim 42 wherein only first Nr rows or Nc columns in the G matrix are computed and remaining data in the G matrix are filled by repeating data in Nr or Nd c column.

44. The method of claim 43 wherein the Nr and Nc are adaptively adjusted based on channel condition.

45. The method of claim 42 wherein each block of samples comprise a middle portion and two edges, whereby the edges overlap to a middle portion of a preceding block and a subsequent block, respectively.

46. The method of claim 45 wherein a size of the block and the edges are adaptively adjusted based on channel condition.

47. The method of claim 30 wherein the parameters are adjusted based on coherence time, Doppler spread and power saving parameters.

48. The method of claim 30 wherein the step of generates rating a channel estimate vector comprises:
correlating the received samples with a known code sequence;
filtering correlation results with smoothing filters; and
performing a post-processing to remove noise-only elements from output of the smoothing filters.

49. The method of claim 48 wherein the known code sequence is a common pilot channel (CPICH) code sequence.

50. The method of claim 48 wherein all elements with a magnitude below a threshold are set to zero during the step of performing a post-processing.

51. The method of claim 50 wherein the threshold is computed as a constant times the magnitude of the largest element in the channel estimate vector.

52. The method of claim 50 wherein the threshold is computed as a constant times an average magnitude of all elements in the channel estimate vector.

53. The method of claim 50 wherein the threshold is selected one of a constant times the magnitude of the largest element in the channel estimate vector and a constant times an average magnitude of all elements in the channel estimate vector.

54. The method of claim 30 wherein the step of generates rating a channel estimate vector comprises:
performing a vector correlation of the received samples with a scrambling code conjugate;
filtering correlation results of the vector correlator with smoothing filters; and
performing a post-processing to remove noise-only elements from output of the smoothing filters.

55. The method of claim 32 wherein the step of estimating the noise power comprises:
calculating magnitude of the received samples;
filtering magnitude values with a smoothing filter; and
multiplying a scaling factor to output of the smoothing filter.
